(19) United States
(12) Patent Application Publication
(10) Pub. No.: US 2026/0231391 A1
(43) Pub. Date: Aug. 6, 2026

(54) SEMICONDUCTOR DEVICES INCLUDING WORD LINES

(71) Applicant: Samsung Electronics Co., Ltd., Suwon-si (KR)

(72) Inventors: Heejae Chae, Suwon-si (KR); Sujin Kang, Suwon-si (KR); Minsoo Kim, Suwon-si (KR); Yongkwan Kim, Suwon-si (KR); Junsoo Kim, Suwon-si (KR); Huijung Kim, Suwon-si (KR); Hyunjin Lee, Suwon-si (KR)

(21) Appl. No.: 19/530,750

(22) Filed: Feb. 5, 2026

(30) Foreign Application Priority Data
Feb. 6, 2025 (KR) 10-2025-0015157

(51) Int. Cl. H10B 12/00

(52) U.S. Cl. CPC H10B 12/00

(57) ABSTRACT

A semiconductor device according to some example implementations of the present disclosure includes: a first channel pattern extending on a substrate in a first direction, the first channel pattern including a first surface and a second surface spaced apart from the first surface in the first direction; a bit line in contact with the first surface of the first channel pattern and extending in a second direction, wherein the second direction intersects the first direction; a second channel pattern in contact with the bit line and adjacent to the first channel pattern and extending in the first direction; an information storage element in contact with the second surface of the first channel pattern; and a word line disposed between the first channel pattern and the second channel pattern and adjacent to the information storage element in the first direction.

### CROSS-REFERENCE TO RELATED APPLICATION(S

Pursuant to 35 U.S.C. § 119(a), this application claims the benefit of an earlier filing date and right of priority to Korean Patent Application No. 10-2025-0015157 filed on February 6, 2025 in the Korean Intellectual Property Office, the disclosure of which is incorporated herein by reference in its entirety.

### BACKGROUND

As demand for high performance, high speed, and/or multifunctionalization of semiconductor devices increases, the degree of integration of semiconductor devices has increased. In manufacturing a semiconductor device having a fine pattern in response to the tendency for high integration of semiconductor devices, it is required to implement patterns having a fine width or a fine separation distance.

### SUMMARY

An aspect of the present disclosure is to provide a semiconductor device including a word line disposed adjacent to both a first channel pattern and a second channel pattern.

A semiconductor device according to example implementations may include: a first channel pattern extending on a substrate in a first direction, the first channel pattern including a first surface and a second surface spaced apart from the first surface in the first direction; a bit line in contact with the first surface of the first channel pattern and extending in a second direction, wherein the second direction intersects the first direction; a second channel pattern in contact with the bit line and adjacent to the first channel pattern and extending in the first direction; an information storage element in contact with the second surface of the first channel pattern; and a word line disposed between the first channel pattern and the second channel pattern and adjacent to the information storage element in the first direction. At least a portion of the word line may extend in a third direction, wherein the third direction intersects the first direction and the second direction. At least a portion of the second channel pattern may overlap the word line and the information storage element in the second direction.

A semiconductor device according to example implementations may include: first channel patterns extending on a substrate in a first direction, the first channel patterns respectively including a first surface and a second surface spaced apart from the first surface in the first direction; bit lines in contact with the first surfaces of the first channel patterns and extending in a second direction intersecting the first direction; second channel patterns in contact with the bit lines and adjacent to the first channel patterns and extending in the first direction; information storage elements in contact with the second surfaces of the first channel patterns; and word lines extending in a third direction, wherein the third direction intersects the first direction and the second direction, between the first channel patterns and the second channel patterns. At least a portion of the second channel patterns overlap the word lines and the information storage elements in the second direction. The information storage elements overlap the first channel patterns and the word lines in the first direction.

A semiconductor device according to example implementations may include: a first channel pattern extending on a substrate in a first direction, the first channel pattern including a first surface and a second surface spaced apart from the first surface in the first direction; a bit line in contact with the first surface of the first channel pattern and extending in a second direction, wherein the second direction intersects the first direction; a second channel pattern in contact with the bit line and adjacent to the first channel pattern, and extending in the first direction; an information storage element in contact with the second surface of the first channel pattern; a word line disposed between the first channel pattern and the second channel pattern and adjacent to the information storage element in the first direction; and a plate electrode spaced apart from the bit line in the first direction and in contact with the second channel pattern. At least a portion of the word line may extend in a third direction, wherein the third direction intersects the first direction and the second direction, the second channel pattern may include a first impurity region in contact with the bit line, a second impurity region spaced apart from the first impurity region in the first direction, and a second channel region between the first impurity region and the second impurity region, and the second channel region may overlap the word line and the information storage element in the second direction.

According to example implementations of the technical concept of the present disclosure, since the word line is disposed adjacent to both the first channel pattern and the second channel pattern, so that the size of the semiconductor device may be reduced.

Advantages and effects of the present application are not limited to the foregoing content and may be more easily understood in the process of describing specific example implementations of the present disclosure.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a schematic perspective view of a semiconductor device according to some example implementations.

FIG. 2 is a circuit diagram of a memory cell of a semiconductor device according to some example implementations.

FIG. 3 illustrates a memory cell according to some example implementations.

FIG. 4A is a schematic perspective view of a semiconductor device including memory cells according to some example implementations.

FIG. 4B is a schematic perspective view of a semiconductor device including memory cells according to some example implementations.

FIGS. 5 to 7 illustrate memory cells according to example implementations.

FIG. 8 illustrates a memory cell according to some example implementations.

FIG. 9 is a schematic perspective view of a semiconductor device including memory cells according to some example implementations.

FIG. 10 illustrates a memory cell according to some example implementations.

FIG. 11A is a schematic perspective view of a semiconductor device including memory cells according to some example implementations.

FIG. 11B is a schematic perspective view of a semiconductor device including memory cells according to some example implementations.

FIG. 12 illustrates a memory cell according to some example implementations.

FIG. 13 is a schematic perspective view of a semiconductor device including memory cells according to some example implementations.

FIGS. 14 and 15 illustrate memory cells according to some example implementations.

FIGS. 16A through 16E illustrate memory cells according to example implementations.

FIGS. 17A to 17C illustrate word lines according to example implementations.

FIGS. 18A to 18C illustrate information storage elements according to example implementations.

### DETAILED DESCRIPTION

Hereinafter, example implementations of the present disclosure will be described with reference to the accompanying drawings.

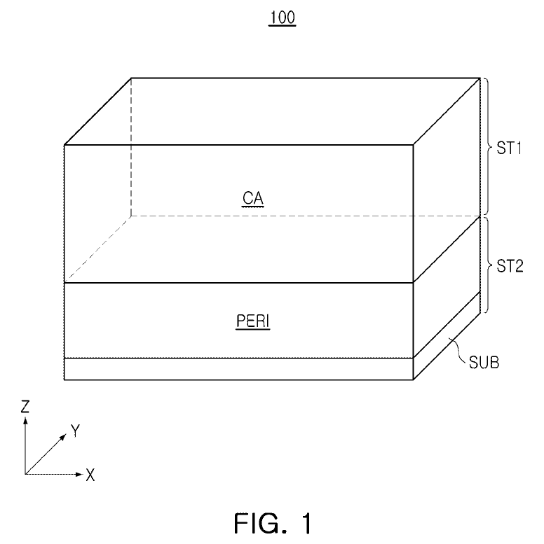

FIG. 1 is a schematic perspective view of a semiconductor device according to some example implementations.

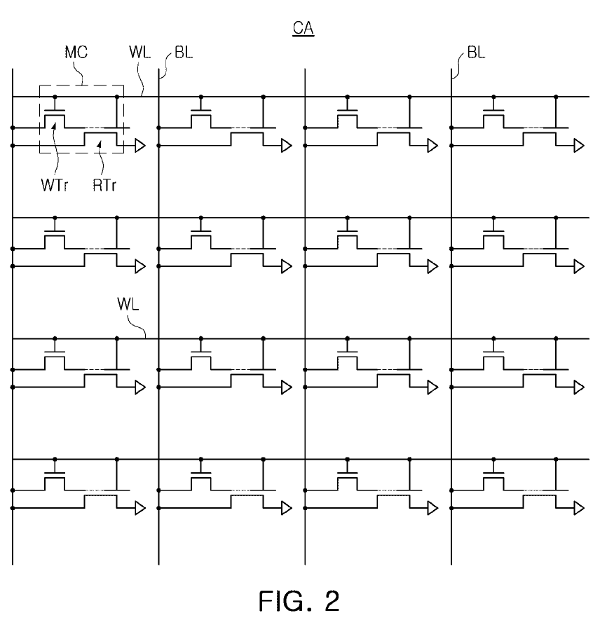

Referring to FIG. 1, a semiconductor device 100 may include a first structure ST1 and a second structure ST2 below the first structure ST1. The first structure ST1 may include a memory cell array CA, and the memory cell array CA may include memory cells MC described below in FIG. 2.

The second structure ST2 may include a peripheral circuit region PERI on a peripheral substrate SUB, and the peripheral circuit region PERI may include peripheral circuit elements including peripheral transistors. For example, logic elements such as an inverter circuit, a NAND gate circuit, a NOR gate circuit, an AND gate circuit, an OR gate circuit, an XOR gate circuit, an XNOR gate circuit, a NOT gate circuit, an antifuse, and the like, may be disposed in the peripheral circuit region PERI. A peripheral circuit region PERI may also include peripheral circuits such as a sense amplifier and a sub-word line driver used for the operation of the memory cells MC, and peripheral circuits for input/output of data or commands or input of power/ground.

In some example implementations, the second structure ST2 may be bonded to the first structure ST1. For example, the first structure ST1 may include first bonding pads on a lower surface thereof, and the second structure ST2 may include second bonding pads bonded to the first bonding pads on an upper surface thereof. The first bonding pads and the second bonding pads may electrically connect the first structure ST1 and the second structure ST2.

In some example implementations, the semiconductor device 100 may include a connection plug penetrating through a bonding surface between the first structure ST1 and the second structure ST2. The connection plug may electrically connect the first structure ST1 and the second structure ST2.

In some example implementations, the second structure ST2 may be disposed on the first structure ST1.

FIG. 2 is a circuit diagram of a memory cell of a semiconductor device according to some example implementations.

Referring to FIG. 2, memory cells MC may be connected to bit lines BL and word lines WL. Each memory cell MC may include a write transistor WTr, a read transistor RTr, and a storage node SN. The storage node SN may function as a gate (e.g., a floating gate) of the read transistor RTr and may be electrically connected to the write transistor WTr. For example, the storage node SN may be electrically connected to a channel of the write transistor WTr.

Each memory cell MC may be selected by the bit lines BL and the word lines WL. Each of the memory cells MC may operate as a DRAM memory cell in which a write operation for storing information and a read operation for reading information are performed, and may not include a capacitor. For example, each of the memory cells MC may store information in a storage node SN instead of a capacitor, and may be referred to as a 2T memory cell.

The write transistor WTr may store charges in the storage node SN. Depending on the amount of charges stored in the storage node SN, a threshold voltage of the read transistor RTr in which the storage node SN functions as a gate may change. Depending on the threshold voltage of the read transistor RTr, information stored in the memory cell may be read as ‘0’ or ‘1.’

One end of the channel of the write transistor WTr may be connected to the bit line BL, and the other end thereof may be connected to the storage node SN. A gate of the write transistor WTr may be electrically connected to the word line WL.

One end of the channel of the read transistor RTr may be connected to the bit line BL, and the other end thereof may be grounded. A gate of the read transistor RTr may be electrically connected to the word line WL. The word line WL may function as the gate of the read transistor RTr together with the storage node SN. For example, the storage node SN and the word line WL may be used for an on/off operation of the read transistor RTr.

The bit line BL may be electrically connected to the memory cell MC. For example, the bit line BL may be electrically connected to a channel of the write transistor WTr and a channel of the read transistor RTr.

According to example implementations of the present disclosure, since the write transistor WTr and the read transistor RTr of the memory cell MC are connected to single word line WL, the integration of the semiconductor device may be increased as compared to a case in which two word lines WL are connected per memory cell MC. Accordingly, a semiconductor device having a smaller size may be implemented. Additionally, the storage node SN may store information and may function as a gate of a read transistor RTr together with a word line WL.

In some example implementations, an array of memory cells MC illustrated in FIG. 2 may be arranged to be parallel to an upper surface of the peripheral substrate SUB, and the arrays may be configured in a plurality of layers. In some example implementations, the array of memory cells MC illustrated in FIG. 2 may be arranged to be perpendicular to the upper surface of the peripheral substrate SUB, and the arrays may be arranged in a horizontal direction.

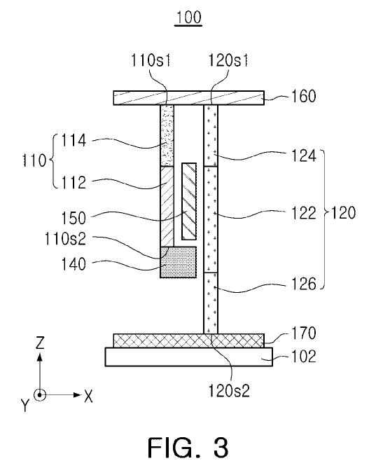

FIG. 3 illustrates a memory cell according to some example implementations.

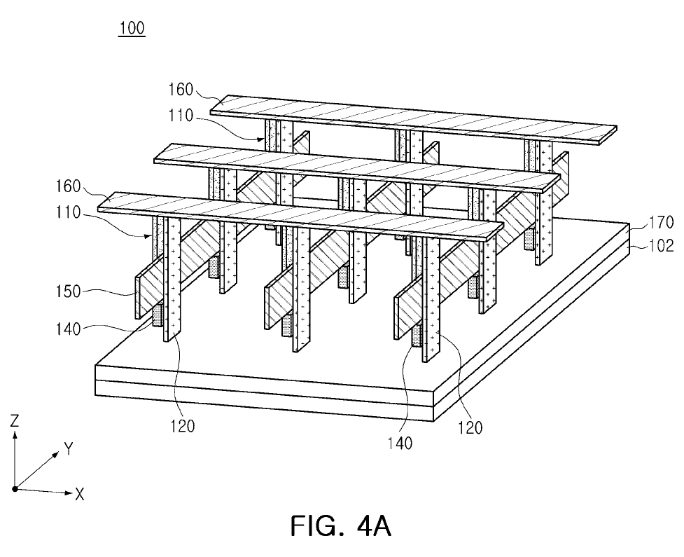

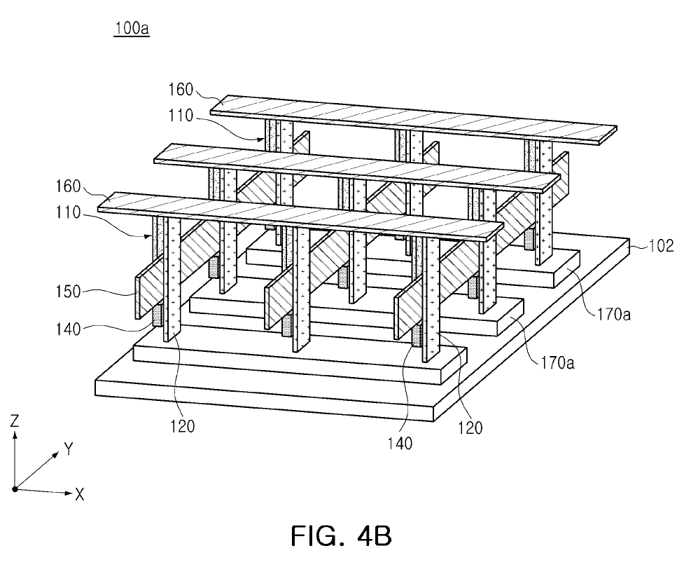

FIG. 4A is a schematic perspective view of a semiconductor device including memory cells according to some example implementations.

Referring to FIGS. 3 and 4A, a semiconductor device 100 according to an embodiment of the present disclosure may include a substrate 102, a first channel pattern 110, a second channel pattern 120, an information storage element 140, a word line 150, a bit line 160, and a plate electrode 170.

The write transistor WTr described with reference to FIG. 2 may include the first channel pattern 110. The read transistor RTr may include the second channel pattern 120. The information storage element 140 may be electrically connected to the first channel pattern 110 and may include a storage node SN described with reference to FIG. 2. The word line 150 may correspond to the word line WL, and the bit line 160 may correspond to the bit line BL.

The first channel pattern 110, the second channel pattern 120, the information storage element 140, the word line 150, the bit line 160 and the plate electrode 170 may form a memory cell MC. That is, FIG. 3 illustrates a unit memory cell MC.

The substrate 102 may include a semiconductor material, such as a group IV semiconductor, a group III-V compound semiconductor, or a group II-VI compound semiconductor. For example, the group IV semiconductor may include silicon, germanium, or silicon-germanium. The substrate 102 may further include impurities. The substrate 102 may be a silicon substrate, a silicon-on-insulator (SOI) substrate, a germanium substrate, a germanium-on-insulator (GOI) substrate, a silicon-germanium substrate, or a substrate including an epitaxial layer. The substrate 102 may be a substrate included in the first structure ST1 or a peripheral substrate SUB included in the second structure ST2. In this specification, ‘vertical direction’ may refer to a direction, perpendicular to an upper surface of the substrate 102. For example, an X-direction and a Y-direction may be directions, parallel to the upper surface of the substrate 102, and a Z-direction may be a direction, perpendicular to the upper surface of the substrate 102.

The first channel patterns 110 may extend in the Z-direction and may be spaced apart from each other in the X-direction and the Y-direction. The first channel pattern 110 may be in contact with the information storage element 140 and the bit line 160. For example, the first channel pattern 110 may include a first surface 110s1 and a second surface 110s2, perpendicular to the Z-direction, and spaced apart from each other in the Z-direction. The first surface 110s1 of the first channel pattern 110 may be in contact with the bit line 160, and the second surface 110s2 of the first channel pattern 110 may be in contact with the information storage element 140. In some example implementations, the first channel pattern 110 may include a first channel region 112 and a channel contact 114. The first channel region 112 may be in contact with the information storage element 140, and the channel contact 114 may be in contact with the bit line 160. As used herein, “extending” includes “being elongated” or “being oriented along.” For example, “extending in the Z-direction” includes “being elongated in Z-direction” or “being oriented along the Z-direction.”

The first channel region 112 may include at least one of a polycrystalline semiconductor material, an oxide semiconductor material such as Indium Gallium Zinc Oxide (IGZO), or a two-dimensional material such as MoS₂. In some example implementations, the first channel region 112 may include an oxide semiconductor material.

The oxide semiconductor material may be indium gallium zinc oxide (IGZO). However, the example implementation is not limited thereto. For example, the oxide semiconductor material may include at least one of Indium Tungsten Oxide (IWO), Indium Tin Gallium Oxide (ITGO), Indium Aluminum Zinc Oxide(IAGO), Indium Gallium Oxide(IGO), Indium Tin Zinc Oxide(ITZO), Zinc Tin Oxide (ZTO), Indium Zinc Oxide (IZO), ZnO, Indium Gallium Silicon Oxide (IGSO), Indium Oxide (InO), Tin Oxide (SnO), Titanium Oxide (TiO), Zinc Oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), and Indium Gallium Silicon Oxide (InGaSiO).

The two-dimensional material may include at least one of a Transition Metal Dichalcogenide material layer (TMD material layer), a black phosphorous material layer, and a hBN material layer (hexagonal Boron-Nitride material layer), which may have semiconductor properties. For example, the two-dimensional material may include at least one of BiOSe, Crl, WSe2, MoS2, TaS, WS, SnSe, ReS, β-SnTe, MnO, AsS, P(black), InSe, h-BN, GaSe, GaN, SrTiO, MXene and Janus 2D materials capable of forming a two-dimensional material.

The channel contact 114 may include doped polysilicon, a metal, a conductive metal nitride, a metal-semiconductor compound, a metal compound, a conductive metal oxide, graphene, a carbon nanotube, or combinations thereof. For example, at least one of the channel contacts 114 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof.

The second channel patterns 120 may extend in the Z-direction and may be spaced apart from each other in the X-direction and the Y-direction. Each of the second channel patterns 120 may be disposed adjacent to a corresponding first channel pattern 110. For example, each of the second channel patterns 120 may overlap first channel pattern 110 respectively corresponding thereto in the X-direction. The second channel pattern 120 may be in contact with the bit line 160 and the plate electrode 170. For example, the second channel pattern 120 may include a first surface 120s1 and a second surface 120s2, which are perpendicular to the Z-direction and spaced apart from each other in the Z-direction. The first surface 120s1 of the second channel pattern 120 may be in contact with the bit line 160, and the second surface 120s2 of the second channel pattern 120 may be in contact with the plate electrode 170.

The second channel pattern 120 may include a single crystal semiconductor material, polysilicon, or an oxide semiconductor material. The single crystal semiconductor material may include, for example, a group IV semiconductor, a group III-V compound semiconductor, or a group II-VI compound semiconductor. The oxide semiconductor material may include IGZO or various oxide semiconductor materials described above.

In some example implementations, the second channel pattern 120 may include a single crystal semiconductor material, and may include a second channel region 122, a first impurity region 124, and a second impurity region 126. The first impurity region 124 may be in contact with the bit line 160. The second impurity region 126 may be spaced apart from the first impurity region 124 in the Z-direction, and may be in contact with the plate electrode 170. The second channel region 122 may be disposed between the first impurity region 124 and the second impurity region 126, and may overlap the first impurity region 124 and the second impurity region 126 in the Z-direction.

The first impurity region 124 and the second impurity region 126 may include impurities. In some example implementations, when the read transistor RTr is an NMOS transistor, the first impurity region 124 and the second impurity region 126 may include N-type impurities, such as P or As. In some example implementations, when the read transistor RTr is a PMOS transistor, the first impurity region 124 and the second impurity region 126 may include P-type impurities, such as B or Al. Even when the second channel pattern 120 includes polysilicon or an oxide semiconductor material, the second channel pattern 120 may include N-type impurities or P-type impurities.

The information storage element 140 may be in contact with the first channel pattern 110 and may be electrically connected to the first channel pattern 110. For example, at least a portion of the information storage element 140 may be in contact with the first channel region 112 and may overlap the first channel region 112 in the Z-direction. The information storage element 140 may be disposed adjacent to the second channel pattern 120. For example, at least a portion of the information storage element 140 may be adjacent to the second channel region 122, and may overlap each other in the X-direction. A width of the information storage element 140 in the X-direction may be greater than a width of the first channel pattern 110 in the X-direction. The information storage element 140 may be spaced apart from the substrate 102 and the plate electrode 170 in the Z-direction.

The information storage element 140 may include a conductive material, for example, doped single crystal silicon, doped polycrystalline silicon, a metal, a conductive metal nitride, a metal-semiconductor compound, a conductive metal oxide, conductive graphene, carbon nanotubes, or combinations thereof.

Although not illustrated in FIG. 3, the semiconductor device 100 may further include gate dielectric layers disposed between the information storage element 140 and the second channel pattern.

The word line 150 may be disposed adjacent to both the first channel pattern 110 and the second channel pattern 120. For example, at least a portion of the word line 150 may extend in the Y-direction between the first channel pattern 110 and the second channel pattern 120. At least a portion of the word line 150 may overlap the first channel region 112 in the X-direction, and may overlap the second channel region 122 in the X-direction. The word line 150 may function as a gate of a write transistor WTr and may also function as a gate of a read transistor RTr. For example, since at least a portion of the information storage element 140 and at least a portion of the word line 150 are adjacent to the second channel region 122, the word line 150 may function as a gate of the read transistor RTr together with the information storage element 140. For example, when the information storage element 140 is charged, the information storage element 140 may function as a gate of the read transistor RTr. The word line 150 may be disposed adjacent to both the first channel pattern 110 and the second channel pattern 120, and may function as a gate of the write transistor WTr and the read transistor RTr, and may improve the integration of the semiconductor device 100. Accordingly, the semiconductor device 100 having a smaller size may be implemented.

The word line 150 may include a metal, a conductive metal nitride, a metal compound, a conductive metal oxide, graphene, a carbon nanotube, or combinations thereof. For example, at least one of the word lines 150 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof.

Although not illustrated in FIG. 3, the semiconductor device 100 may further include gate dielectric layers disposed between the word line 150 and the first channel pattern 110 and between the word line 150 and the second channel pattern.

The bit lines 160 may extend in the X-direction and may be spaced apart from each other in the Y-direction. The bit lines 160 may be in contact with the first channel patterns 110 and the second channel patterns 120 and may be electrically connected. For example, the bit lines 160 may be in contact with the first surfaces 110s1 of the first channel patterns 110 and the first surfaces 120s1 of the second channel patterns 120.

The bit lines 160 may include doped polysilicon, a metal, a conductive metal nitride, a metal-semiconductor compound, a metal compound, a conductive metal oxide, graphene, carbon nanotubes, or combinations thereof. For example, at least one of the bit lines 160 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof.

In some example implementations, the bit lines 160 may include a plurality of sequentially stacked conductive layers. For example, the conductive layers may include at least one of doped polycrystalline silicon, a silicide material or a metal. However, according to example implementations, the number of layers and the type of material of the bit lines 160 may be variously changed.

The plate electrode 170 may be in contact with the second channel patterns 120. For example, the plate electrode 170 may be in contact with the second surfaces 120s2 of the second channel patterns 120. In FIG. 3, a single plate electrode 170 is illustrated as being in contact with a plurality of second channel patterns 120, but the present disclosure is not limited thereto. According to some example implementations, a plurality of plate electrodes 170 may be disposed, and each plate electrode 170 may be in contact with a plurality of second channel patterns 120. In some example implementations, the plate electrode 170 may be electrically grounded.

The plate electrode 170 may include a metal, a conductive metal nitride, a metal compound, a conductive metal oxide, graphene, a carbon nanotube, or combinations thereof. For example, the plate electrode 170 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof.

FIG. 4B is a schematic perspective view of a semiconductor device including memory cells according to some example implementations.

Referring to FIG. 4B, a semiconductor device 100a may include plate electrodes 170a in contact with second channel patterns 120. The plate electrodes 170a may extend in the X-direction and may be spaced apart from each other in the Y-direction. Each plate electrode 170a may be in contact with a plurality of second channel patterns 120.

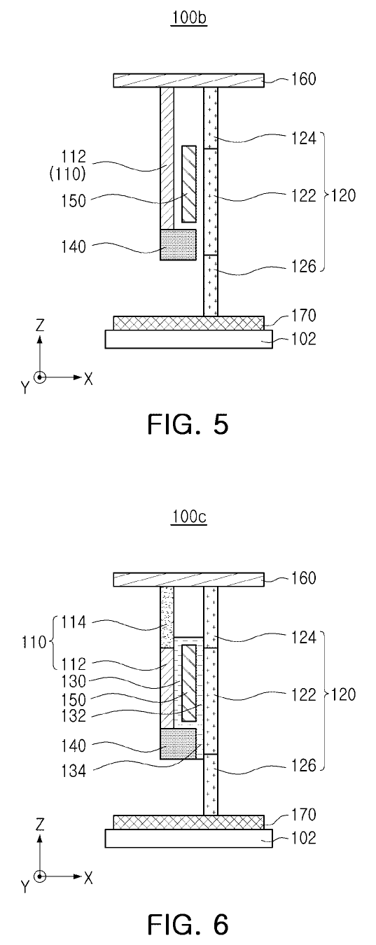

FIGS. 5 to 7 illustrate memory cells according to example implementations.

Referring to FIG. 5, a semiconductor device 100b may include a first channel pattern 110 in contact with the information storage element 140 and the bit line 160. In some example implementations, the channel contact 114 may be omitted, and the first channel pattern 110 may be formed of a single material. For example, the first channel region 112 may extend in the Z-direction to contact both the information storage element 140 and the bit line 160.

Referring to FIG. 6, a semiconductor device 100c may further include dielectric structures 130, 132 and 134. The dielectric structures 130, 132 and 134 may cover the first channel region 112 of the first channel pattern 110, and may cover the second channel region 122 of the second channel pattern 120. For example, the dielectric structures 130, 132 and 134 may include a first gate dielectric layer 130, a second gate dielectric layer 132, and a third gate dielectric layer 134. The first gate dielectric layer 130 may be disposed between the first channel region 112 and the word line 150, and may be included in a write transistor WTr. The second gate dielectric layer 132 may be disposed between the second channel region 122 and the word line 150, and the third gate dielectric layer 134 may be disposed between the second channel region 122 and the information storage element 140. The second gate dielectric layer 132 and the third gate dielectric layer 134 may form a read transistor RTr.

In some example implementations, the first gate dielectric layer 130, the second gate dielectric layer 132, and the third gate dielectric layer 134 may include the same material, and may be monolithically formed. For example, the dielectric structures 130, 132 and 134 may surround the word line 150, and may extend between the second channel region 122 and the information storage element 140. The dielectric structures 130, 132 and 134 are illustrated as being in contact with the channel contact 114, the first impurity region 124, and the second impurity region 126, but the present disclosure is not limited thereto. In some example implementations, the dielectric structures 130, 132 and 134 may be spaced apart from at least one of the channel contact 114, the first impurity region 124 or the second impurity region 126.

The dielectric structures 130, 132 and 134 may include at least one of silicon oxide and a high-κ dielectric. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto. The dielectric structures 130, 132 and 134 may be formed of a single layer or multiple layers of the materials described above.

In another example, each of the dielectric structures 130, 132 and 134 may include an information storage layer and a dielectric layer. For example, each of the dielectric structures 130, 132 and 134 may include a ferroelectric layer that may have polarization characteristics depending on an electric field and may have remnant polarization due to a dipole even in the absence of an external electric field. Data may be recorded using the polarization state within the ferroelectric layer. Accordingly, each of the dielectric structures 130, 132 and 134 may include a ferroelectric layer that may be referred to as an information storage layer. The ferroelectric layer that may be the information storage layer may include a Hf-based compound, a Zr-based compound, and/or a Hf-Zr-based compound. For example, the Hf-based compound may be a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with impurities, for example, at least one of C, Si, Mg, Al, Y, N, Ge, Sn, Gd, La, Sc, or Sr. For example, the ferroelectric layer, which may be the information storage layer, may be a material in which at least one of HfO₂, ZrO₂, or HZrO is doped with impurities, for example, at least one of C, Si, Mg, Al, Y, N, Ge, Sn, Gd, La, Sc or Sr.

In the dielectric structures 130, 132 and 134, the information storage layer is not limited to the above-described material type and may include a material capable of storing information.

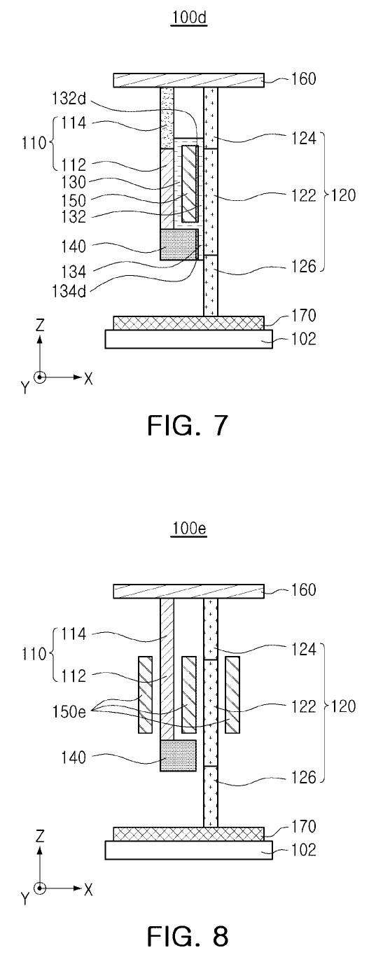

Referring to FIG. 7, a semiconductor device 100d may further include work function control layers 132d and 134d. The work function control layers 132d and 134d may include a first work function control layer 132d and a second work function control layer 134d. The first work function control layer 132d may be disposed between the word line 150 and the second channel region 122. For example, the first work function control layer 132d may be disposed on a surface of the word line 150. The second work function control layer 134d may be disposed between the information storage element 140 and the second channel region 122. For example, the second work function control layer 134d may be disposed on a surface of the information storage element 140. In some example implementations, the semiconductor device 100d may further include a work function control layer disposed between the word line 150 and the first channel region 112.

The work function control layers 132d and 134d may be used to adjust a threshold voltage of the read transistor RTr. For example, the work function control layers 132d and 134d may include a material different from that of the word line 150 and may include a material having a work function different from that of the word line 150. In some example implementations, the work function control layers 132d and 134d may include at least one of a metal, a metal nitride or polycrystalline silicon. For example, the work function control layers 132d and 134d may include at least one of Ti, Ta, W, TiN, TaN, WN or polycrystalline silicon. The work function control layers 132d and 134d may further include a work function control element, and the work function control element may include at least one of La, Sr, Sb, Y, Al, Ta, Hf, Ir, Zr or Mg. In some example implementations, the first work function control layer 132d and the second work function control layer 134d may include materials having different work functions.

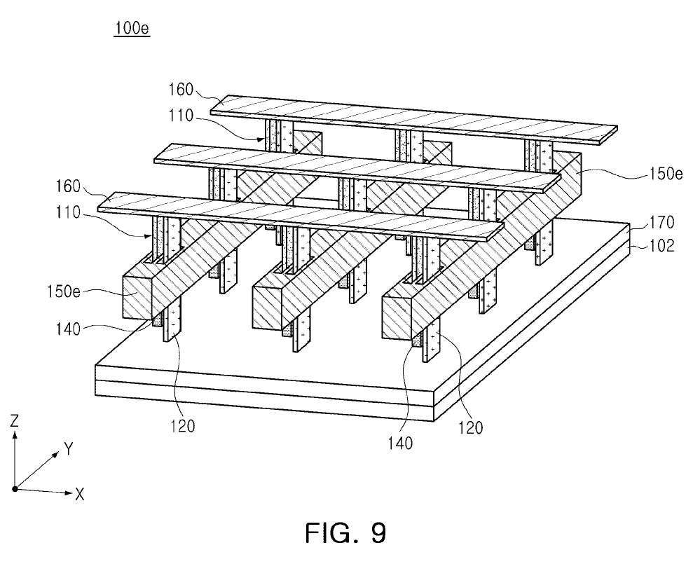

FIG. 8 illustrates a memory cell according to some example implementations. FIG. 9 is a schematic perspective view of a semiconductor device including memory cells according to some example implementations.

Referring to FIGS. 8 and 9, a semiconductor device 100e may include a word line 150e adjacent to a first channel pattern 110 and a second channel pattern 120. In some example implementations, the word line 150e may have a gate-all-around structure surrounding the first channel pattern 110 and the second channel pattern 120. For example, at least a portion of the word line 150e may extend in the Y-direction while surrounding the first channel pattern 110 and the second channel pattern 120. The word line 150e may include a plurality of surfaces facing the first channel region 112, and may include a plurality of surfaces facing the second channel region 122. Side surfaces, perpendicular to the X-direction of the first channel region 112, and side surfaces, perpendicular to the Y-direction of the first channel region 112, may face the word line 150e. The side surfaces, perpendicular to the X-direction of the second channel region 122, and the side surfaces, perpendicular to the Y-direction of the second channel region 122, may face the word line 150e.

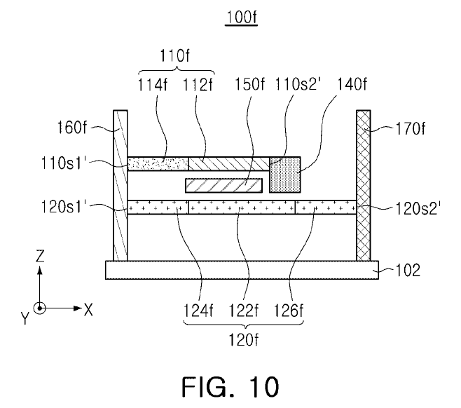

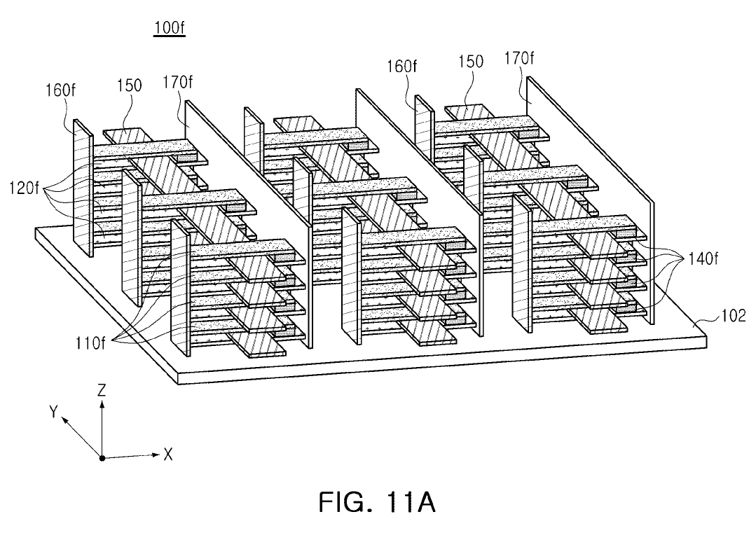

FIG. 10 illustrates a memory cell according to some example implementations. FIG. 11A is a schematic perspective view of a semiconductor device including memory cells according to some example implementations.

Referring to FIG. 10 and FIG. 11A, a semiconductor device 100f may include a first channel pattern 110f, a second channel pattern 120f, an information storage element 140f, a word line 150f, a bit line 160f, and a plate electrode 170f. The first channel pattern 110f, the second channel pattern 120f, the information storage element 140f, the word line 150f, the bit line 160f, and the plate electrode 170f may form a memory cell MC. That is, FIG. 10 illustrates a unit memory cell MC.

The first channel patterns 110f may extend in the X-direction, and may be spaced apart from each other in the Y-direction and the Z-direction. The first channel pattern 110f may be in contact with the information storage element 140f and the bit line 160f. For example, the first channel pattern 110f may include a first surface 110s1’ and a second surface 110s2’ which are perpendicular to the X-direction and spaced apart from each other in the X-direction. The first surface 110s1’ of the first channel pattern 110f may be in contact with the bit line 160f, and the second surface 110s2’ of the first channel pattern 110f may be in contact with the information storage element 140f. In some example implementations, the first channel pattern 110f may include a first channel region 112f and a channel contact 114f. The first channel region 112f may be in contact with the information storage element 140f, and the channel contact 114f may be in contact with the bit line 160f.

The second channel patterns 120f may extend in the X-direction and may be spaced apart from each other in the Y-direction and the Z-direction. Each of the second channel patterns 120f may be disposed adjacent to the first channel patterns 110f corresponding thereto. For example, each of the second channel patterns 120f may overlap first channel patterns 110f corresponding thereto in the Z-direction. The second channel pattern 120f may be in contact with the bit line 160f and the plate electrode 170f. For example, the second channel pattern 120f may include a first surface 120s1’ and a second surface 120s2’ which are perpendicular to the X-direction and spaced apart from each other in the X-direction. The first surface 120s1’ of the second channel pattern 120f may be in contact with the bit line 160f, and the second surface 120s2’ of the second channel pattern 120f may be in contact with the plate electrode 170f.

In some example implementations, the second channel pattern 120f may include a single crystal semiconductor material, and may include a second channel region 122f, a first impurity region 124f, and a second impurity region 126f. The first impurity region 124f may be in contact with the bit line 160f. The second impurity region 126f may be spaced apart from the first impurity region 124f in the X-direction, and may be in contact with the plate electrode 170f. The second channel region 122f may be disposed between the first impurity region 124f and the second impurity region 126f, and may overlap the first impurity region 124f and the second impurity region 126f in the X-direction.

The information storage element 140f may be in contact with the first channel pattern 110f, and may be electrically connected to the first channel pattern 110f. For example, at least a portion of the information storage element 140f may be in contact with the first channel region 112f, and may overlap the first channel region 112f in the X-direction. The information storage element 140f may be disposed adjacent to the second channel pattern 120f. For example, at least a portion of the information storage element 140f may be adjacent to the second channel region 122f, and may overlap the second channel region 122f in the Z-direction. A width of the information storage element 140f in the Z-direction may be greater than a width of the first channel pattern 110f in the Z-direction. The information storage element 140f may be spaced apart from the plate electrode 170f in the X-direction.

The word line 150f may be disposed adjacent to both the first channel pattern 110f and the second channel pattern 120f. For example, at least a portion of the word line 150f may extend in the Y-direction between the first channel pattern 110f and the second channel pattern 120f. At least a portion of the word line 150f may overlap the first channel region 112f in the Z-direction, and may overlap the second channel region 122f in the Z-direction. The word lines 150f may be spaced apart from each other in the X-direction and the Z-direction.

The bit lines 160f may extend in the Z-direction and may be spaced apart from each other in the X-direction and the Y-direction. The bit lines 160f may be in contact with the first channel patterns 110f and the second channel patterns 120f and may be electrically connected thereto. For example, the bit lines 160f may be in contact with the first surfaces 110s1’ of the first channel patterns 110f and the first surfaces 120s1’ of the second channel patterns 120f.

The plate electrode 170f may be in contact with the second channel patterns 120f. For example, the plate electrode 170f may be in contact with the second surfaces 120s2’ of the second channel patterns 120f. In FIG. 11A, a single plate electrode 170f is illustrated as being in contact with a plurality of second channel patterns 120f, but the present disclosure is not limited thereto.

In some example implementations, the semiconductor device 100f may be manufactured by forming a stack structure on a substrate 102, and then forming word lines 150f spaced apart from each other in the Z-direction within the stack structure at once. For example, the stack structure may be formed by alternately stacking a semiconductor material including the same material as the second channel pattern 120f and a sacrificial material having an etching selectivity with the semiconductor material. In some example implementations, the semiconductor device 100f may be manufactured by stacking memory cells comprised of the first channel pattern 110f, the second channel pattern 120f, the information storage element 140f and the word line 150f one layer at a time on the substrate 102.

FIG. 11B is a schematic perspective view of a semiconductor device including memory cells according to some example implementations.

Referring to FIG. 11B, a semiconductor device 100g may include plate electrodes 170g in contact with second channel patterns 120f. The plate electrodes 170g may extend in the Z-direction and may be spaced apart from each other in the X-direction and the Y-direction. Each plate electrode 170g may be in contact with a plurality of second channel patterns 120f.

Referring to FIGS. 11A and 11B, the semiconductor devices 100f and 100g each may include memory cells stacked in the Z-direction on the substrate 102. The first channel patterns 110f and the second channel patterns 120f may be disposed alternately in the Z-direction. Each of the bit lines 160f may be in contact with a plurality of first channel patterns 110f and a plurality of second channel patterns 120f, and each of the plate electrodes 170f and 170g may be in contact with a plurality of second channel patterns 120f. For example, the first channel patterns 110f may include a first upper channel pattern and a first lower channel pattern spaced apart from each other in the Z-direction. The second channel patterns 120f may include a second upper channel pattern adjacent to the first upper channel pattern and a second lower channel pattern adjacent to the first lower channel pattern, which are spaced apart from each other in the Z-direction. The word lines 150f may include an upper word line extending between the first upper channel pattern and the second upper channel pattern, and a lower word line extending between the first lower channel pattern and the second lower channel pattern.

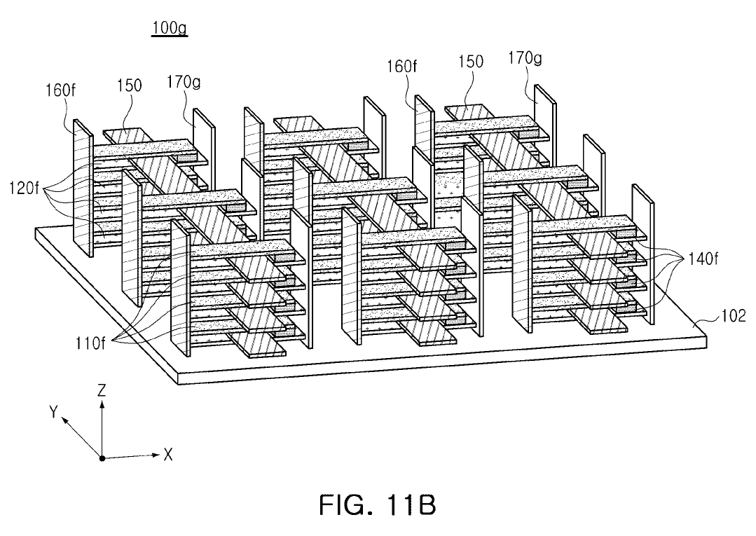

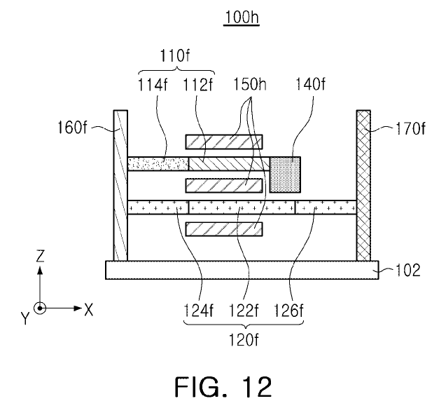

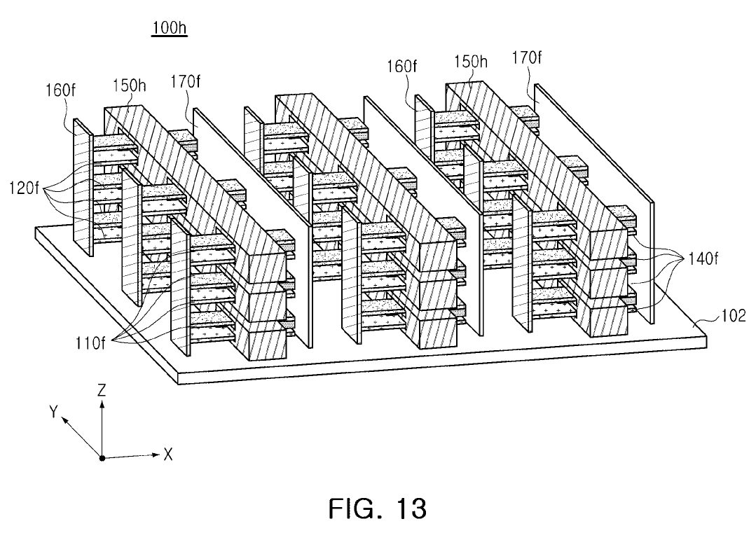

FIG. 12 illustrates a memory cell according to some example implementations. FIG. 13 is a schematic perspective view of a semiconductor device including memory cells according to some example implementations.

Referring to FIGS. 12 and 13, a semiconductor device 100h may include a word line 150h adjacent to the first channel pattern 110f and the second channel pattern 120f. In some example implementations, the word line 150h may have a gate-all-around structure surrounding the first channel pattern 110f and the second channel pattern 120f. For example, at least a portion of the word line 150h may extend in the Y-direction while surrounding the first channel pattern 110f and the second channel pattern 120f. The word line 150h may include a plurality of surfaces facing the first channel region 112f, and may include a plurality of surfaces facing the second channel region 122f. Side surfaces, perpendicular to the Y-direction of the first channel region 112f, and side surfaces, perpendicular to the Z-direction of the first channel region 112f, may face the word line 150h. Side surfaces, perpendicular to the Y-direction of the second channel region 122, and side surfaces, perpendicular to the Z-direction of the second channel region 122, may face the word line 150h.

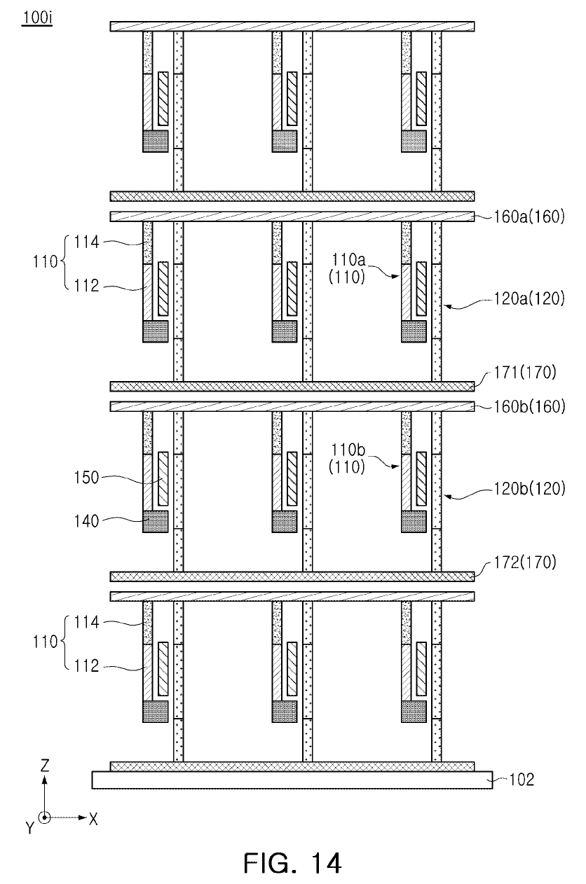

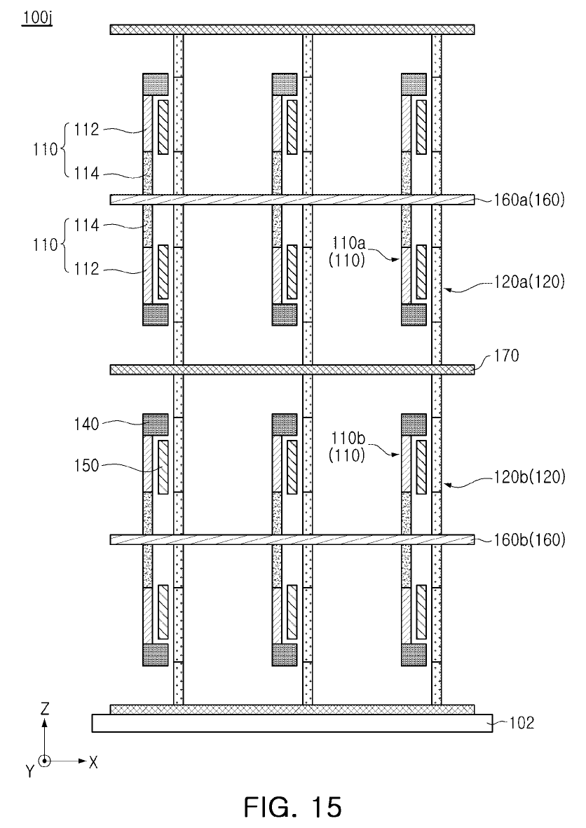

FIGS. 14 and 15 illustrate memory cells according to example implementations.

Referring to FIG. 14, a semiconductor device 100i may include memory cells stacked in the Z-direction on a substrate 102. The memory cells may be included in at least one of the semiconductor devices 100, 100a, 100b, 100c, 100d and 100e described with reference to FIGS. 3 to 9, and each of memory cells may include a first channel pattern 110, a second channel pattern 120, an information storage element 140, a word line 150, a bit line 160, and a plate electrode 170. For example, the first channel patterns 110 may extend in the Z-direction and may be spaced apart from each other in the Z-direction. The second channel patterns 120 may extend in the Z-direction, and may be spaced apart from each other in the Z-direction. The bit lines 160 and the plate electrodes 170 may extend in the X-direction, and may be spaced apart from each other in the Z-direction.

In some example implementations, the bit lines 160 and the plate electrodes 170 may be disposed alternately in the Z-direction. Each of the bit lines 160 may be in contact with a single first channel pattern 110 and a single second channel pattern 120, and each of the plate electrodes 170 may be in contact with one second channel pattern 120. For example, the first channel patterns 110 may include a first channel pattern 110a and a first channel pattern 110b adjacent in the Z-direction, and the second channel patterns 120 may include a second channel pattern 120a and a second channel pattern 120b adjacent in the Z-direction. The first channel pattern 110a and the first channel pattern 110b may be disposed adjacent to the second channel pattern 120a and the second channel pattern 120b in the X-direction, respectively. The bit lines 160 may include a bit line 160a and a bit line 160b adjacent in the Z-direction, and the plate electrodes 170 may include a plate electrode 171 and a plate electrode 172 adjacent in the Z-direction. The bit line 160a, the plate electrode 171, the bit line 160b and the plate electrode 172 may be sequentially disposed in the Z-direction. The bit line 160a may be in contact with the first channel pattern 110a and the second channel pattern 120a, and the plate electrode 171 may be in contact with the second channel pattern 120a. The bit line 160b may be in contact with the first channel pattern 110b and the second channel pattern 120b, and the plate electrode 172 may be in contact with the second channel pattern 120b. The first channel pattern 110a and the second channel pattern 120a may be disposed between the bit line 160a and the bit line 160b, and the first channel pattern 110b and the second channel pattern 120b may not be disposed between the bit line 160a and the bit line 160b, and may be disposed below the bit line 160b.

In this specification, the first channel pattern 110a and the first channel pattern 110b may be referred to as a first upper channel pattern and a first lower channel pattern, respectively. The second channel pattern 120a and the second channel pattern 120b may be referred to as a second upper channel pattern and a second lower channel pattern, respectively. The bit line 160a and the bit line 160b may be referred to as the upper bit line and the lower bit line, respectively. The plate electrode 171 and the plate electrode 172 may be referred to as an upper plate electrode and a lower plate electrode, respectively.

Referring to FIG. 15, a semiconductor device 100j may include memory cells stacked in the Z-direction on the substrate 102.

In some example implementations, the bit lines 160 and the plate electrodes 170 may be alternately disposed in the Z-direction. The memory cells adjacent in the Z-direction may share the bit line 160 and the plate electrode 170. For example, each bit line 160 may be in contact with two first channel patterns 110 and two second channel patterns 120, and each plate electrode 170 may be in contact with two second channel patterns 120. The first channel patterns 110 adjacent to each other in the Z-direction may be disposed symmetrically around the corresponding bit line 160. For example, the channel contacts 114 of the first channel patterns 110 adjacent to each other in the Z-direction may be in contact with the bit line 160. Upper surfaces and lower surfaces of the bit lines 160 may be in contact with the first channel patterns 110 and second channel patterns 120 respectively corresponding thereto. Upper surfaces and lower surfaces of the plate electrodes 170 may be in contact with the second channel patterns 120 respectively corresponding thereto. The first channel pattern 110a, the first channel pattern 110b, the second channel pattern 120a and the second channel pattern 120b may all be disposed between the bit line 160a and the bit line 160b.

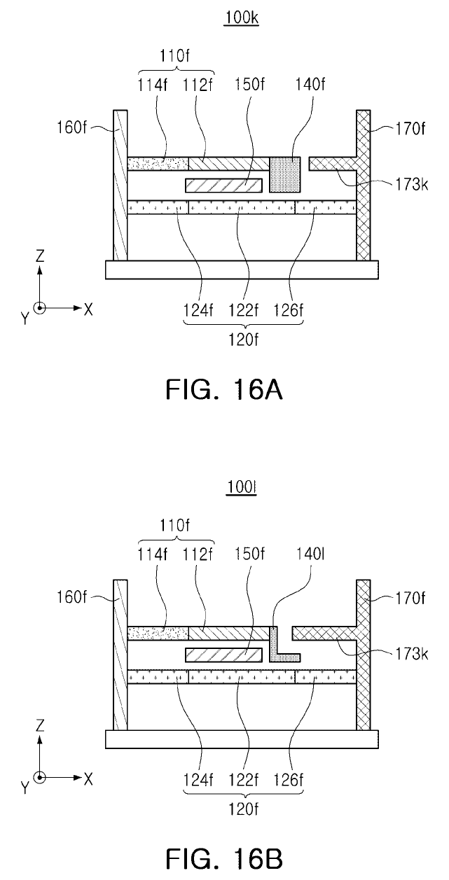

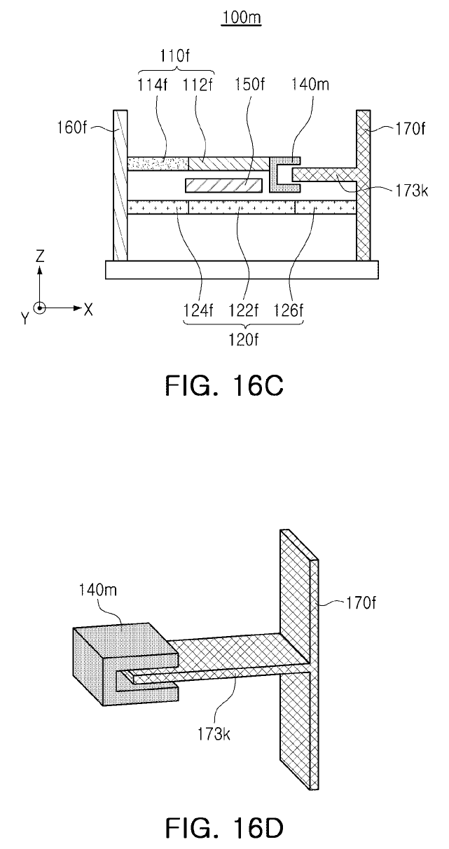

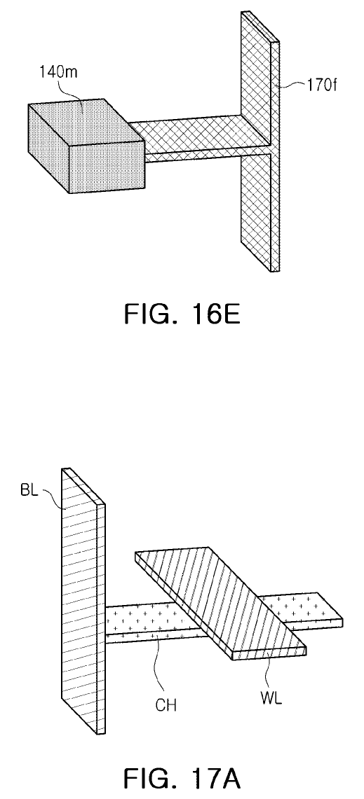

FIGS. 16A to 16E illustrate memory cells according to example implementations. Referring to FIG. 16A, a semiconductor device 100k may include a plate electrode 170f. In some example implementations, the plate electrode 170f may include a protrusion portion 173k extending toward the information storage element 140f. The protrusion portion 173k may extend in a direction, which intersects the direction in which the plate electrode 170f extends. In some example implementations, the plate electrode 170f may extend in the Z-direction, and the protrusion portion 173k may extend in the X-direction. In example implementations of the semiconductor devices 100, 100a, 100b, 100c, 100d and 100e described with reference to FIGS. 3 to 9, the plate electrode 170 may extend in the X-direction, and the protrusion portion 173k may extend in the Z-direction.

Since the plate electrode 170f includes a protrusion portion 173k extending toward the information storage element 140f, a distance between the information storage element 140f and the plate electrode 170f may be reduced. As described above, since the plate electrode 170f is electrically grounded, the information storage element 140f and the plate electrode 170f may be disposed close to each other to prevent the information storage element 140f from being electrically coupled to the word line 150f.

Referring to FIG. 16B, the plate electrode 170f of the semiconductor device 100l may include a protrusion portion 173k extending toward an information storage element 140l. In some example implementations, the information storage element 140l may include a plurality of side surfaces facing the protrusion portion 173k. For example, a portion of the information storage element 140l may overlap the protrusion portion 173k in the X-direction, and a portion of the information storage element 140l may overlap the protrusion portion 173k in the Z-direction.

Referring to FIG. 16C, the plate electrode 170f of a semiconductor device 100m may include a protrusion portion 173k extending toward the information storage element 140f. In some example implementations, an information storage element 140m may include a plurality of side surfaces facing the protrusion portion 173k. For example, the information storage element 140m may include side surfaces overlapping the protrusion portion 173k in the X-direction and side surfaces overlapping the protrusion portion 173k in the Z-direction. At least three side surfaces of the information storage element 140m may overlap the protrusion portion 173k.

Referring to FIGS. 16D and 16E, at least three side surfaces of the information storage element 140m may overlap the protrusion portion 173k. For example, FIG. 16D illustrates that the information storage element 140m has a U-shape, and three side surfaces of the information storage element 140m overlap the protrusion portion 173k. FIG. 16E illustrates that the information storage element 140m surrounds the protrusion portion 173k. For example, four side surfaces of the information storage element 140m may overlap the protrusion portion 173k.

The components according to each example embodiment of the semiconductor devices 100, 100a, 100b, 100c, 100d, 100e, 100f, 100g, 100h, 100i, 100j, 100k, 100l and 100m of the present disclosure may also be applied to other implementations of the semiconductor devices 100, 100a, 100b, 100c, 100d, 100e, 100f, 100g, 100h, 100i, 100j, 100k, 100l and 100m.

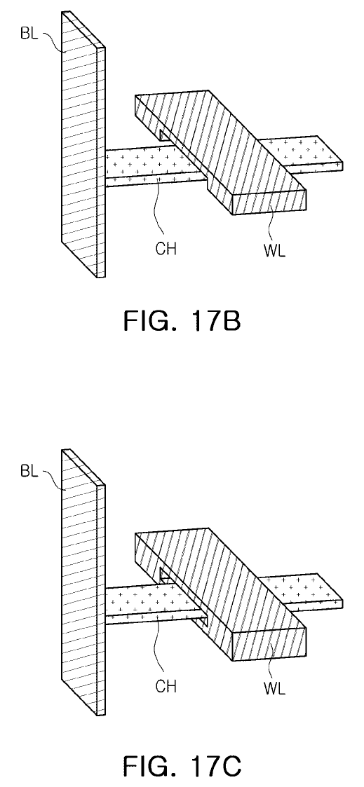

FIGS. 17A to 17C illustrate word lines according to example implementations. FIGS. 17A to 17C illustrate a bit line BL in contact with a channel pattern CH and a word line WL disposed adjacent to the channel pattern CH. The channel pattern CH may correspond to the first channel patterns or the second channel patterns of the semiconductor devices 100, 100a, 100b, 100c, 100d, 100e, 100f, 100g, 100h, 100i, 100j, 100k, 100l and 100m described with reference to FIGS. 3 to 16E. The bit line BL and the word line WL may correspond to the bit lines and the word lines of the semiconductor devices 100, 100a, 100b, 100c, 100d, 100e, 100f, 100g, 100h, 100i, 100j, 100k, 100l, 100m described with reference to FIGS. 3 to 16e, respectively.

Referring to FIG. 17A, the word line WL may have one side surface facing the channel pattern CH. For example, the word line WL may overlap one side surface of the channel pattern CH. Referring to FIG. 17B, the word line WL may have a plurality of side surfaces facing the channel pattern CH. For example, the word line WL may overlap three side surfaces of the channel pattern CH. Referring to FIG. 17C, the word line WL may have a plurality of side surfaces facing the channel pattern CH. For example, the word line WL may surround the channel pattern CH and overlap four side surfaces of the channel pattern CH.

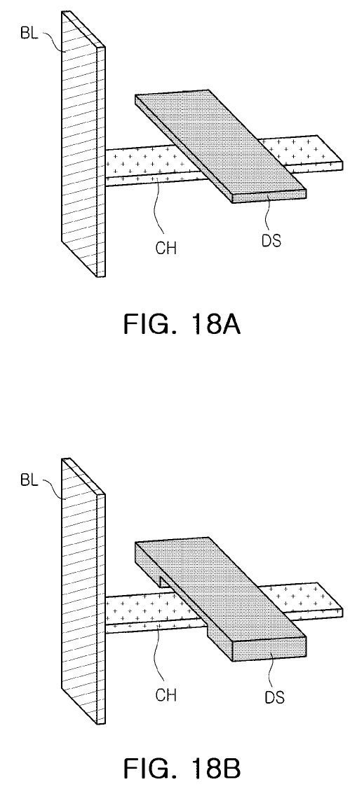

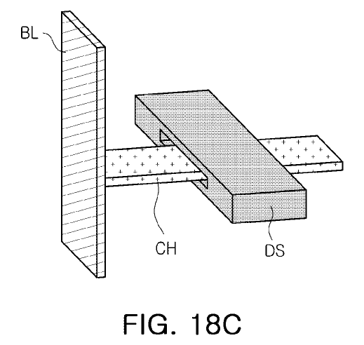

FIGS. 18A to 18C illustrate information storage elements according to example implementations.

FIGS. 18A to 18C illustrate a bit line BL in contact with the channel pattern CH and an information storage element DS disposed adjacent to the channel pattern CH. The channel pattern CH may correspond to the second channel patterns of the semiconductor devices 100, 100a, 100b, 100c, 100d, 100e, 100f, 100g, 100h, 100i, 100j, 100k, 100l and 100m described with reference to FIGS. 3 to 16E. The bit line BL and the information storage element DS may correspond to the bit lines and the information storage element of the semiconductor devices 100, 100a, 100b, 100c, 100d, 100e, 100f, 100g, 100h, 100i, 100j, 100k, 100l and 100m described with reference to FIGS. 3 to 16E, respectively.

Referring to FIG. 18A, the information storage element DS may have one side surface facing the channel pattern CH. For example, the information storage element DS may overlap one side surface of the channel pattern CH. Referring to FIG. 18B, the information storage element DS may have a plurality of side surfaces facing the channel pattern CH. For example, the information storage element DS may overlap three side surfaces of the channel pattern CH. Referring to FIG. 18C, the information storage element DS may have a plurality of side surfaces facing the channel pattern CH. For example, the information storage element DS may surround the channel pattern CH and overlap four side surfaces of the channel pattern CH.

The present disclosure is not limited to the above-described implementations and the accompanying drawings but is defined by the appended claims. Therefore, those of ordinary skill in the art may make various replacements, modifications, or changes, and combinations of example implementations without departing from the scope of the present disclosure defined by the appended claims, and these replacements, modifications, or changes should be construed as being included in the scope of the present disclosure.

What is claimed is:

1. A semiconductor device comprising:
a first channel pattern extending on a substrate in a first direction, the first channel pattern including a first surface and a second surface spaced apart from the first surface in the first direction;
a bit line in contact with the first surface of the first channel pattern and extending in a second direction, wherein the second direction intersects the first direction;
a second channel pattern in contact with the bit line and adjacent to the first channel pattern and extending in the first direction;
an information storage element in contact with the second surface of the first channel pattern; and
a word line disposed between the first channel pattern and the second channel pattern and adjacent to the information storage element in the first direction,
wherein at least a portion of the word line extends in a third direction, wherein the third direction intersects the first direction and the second direction, and
wherein at least a portion of the second channel pattern overlaps the word line and the information storage element in the second direction.

2. The semiconductor device of claim 1, wherein the first direction is perpendicular to an upper surface of the substrate, and
wherein the second direction and the third direction are parallel to the upper surface of the substrate.

3. The semiconductor device of claim 1, wherein the first direction and the third direction are parallel to an upper surface of the substrate, and
wherein the second direction is perpendicular to the upper surface of the substrate.

4. The semiconductor device of claim 1, comprising:
a first gate dielectric layer between the first channel pattern and the word line;
a second gate dielectric layer between the second channel pattern and the word line; and
a third gate dielectric layer between the second channel pattern and the information storage element.

5. The semiconductor device of claim 4, wherein the first gate dielectric layer, the second gate dielectric layer, and the third gate dielectric layer include a same material and are monolithically formed.

6. The semiconductor device of claim 4, comprising:
a first work function control layer between the word line and the second gate dielectric layer; and
a second work function control layer between the information storage element and the third gate dielectric layer,
wherein the first work function control layer and the second work function control layer include a different material from the word line.

7. The semiconductor device of claim 1, wherein the first channel pattern includes a channel contact in contact with the bit line and a first channel region between the channel contact and the information storage element, and
wherein the first channel region includes an oxide semiconductor material.

8. The semiconductor device of claim 1, wherein the first channel pattern includes a first channel region in contact with the bit line and the information storage element, and wherein the first channel pattern includes an oxide semiconductor material.

9. The semiconductor device of claim 1, wherein the second channel pattern includes a first impurity region in contact with the bit line, a second impurity region spaced apart from the first impurity region in the first direction, and a second channel region between the first impurity region and the second impurity region, and
wherein the second channel region overlaps the word line and the information storage element in the second direction.

10. The semiconductor device of claim 1, comprising:
a plate electrode spaced apart from the bit line in the first direction and in contact with the second channel pattern,
wherein the plate electrode includes a protrusion portion extending in the first direction toward the information storage element.

11. The semiconductor device of claim 10, wherein the information storage element includes a plurality of side surfaces facing the protrusion portion.

12. A semiconductor device comprising:
first channel patterns extending on a substrate and extending in a first direction, the first channel patterns respectively including a first surface and a second surface spaced apart from the first surface in the first direction;
bit lines in contact with the first surfaces of the first channel patterns and extending in a second direction intersecting the first direction;
second channel patterns in contact with the bit lines and adjacent to the first channel patterns and extending in the first direction;
information storage elements in contact with the second surfaces of the first channel patterns; and
word lines extending in a third direction, wherein the third direction intersects the first direction and the second direction, between the first channel patterns and the second channel patterns,
wherein at least a portion of the second channel patterns overlap the word lines and the information storage elements in the second direction, and
wherein the information storage elements overlap the first channel patterns and the word lines in the first direction.

13. The semiconductor device of claim 12, wherein the first channel patterns are spaced apart from each other in the third direction, and
wherein the bit lines are spaced apart from each other in the third direction.

14. The semiconductor device of claim 12, wherein the first direction and the third direction are parallel to an upper surface of the substrate, and
wherein the second direction is perpendicular to the upper surface of the substrate.

15. The semiconductor device of claim 14, wherein the first channel patterns include a first upper channel pattern and a first lower channel pattern spaced apart from each other in the second direction,
wherein the second channel patterns include a second upper channel pattern adjacent to the first upper channel pattern and a second lower channel pattern adjacent to the first lower channel pattern, which are spaced apart from each other in the second direction, and
wherein the word lines include an upper word line extending between the first upper channel pattern and the second upper channel pattern, and a lower word line extending between the first lower channel pattern and the second lower channel pattern.

16. The semiconductor device of claim 12, wherein the first direction is perpendicular to an upper surface of the substrate, and
wherein the second direction and the third direction are parallel to the upper surface of the substrate.

17. The semiconductor device of claim 16, wherein the first channel patterns include a first upper channel pattern and a first lower channel pattern spaced apart from each other in the first direction, and
wherein the second channel patterns include a second upper channel pattern adjacent to the first upper channel pattern and a second lower channel pattern adjacent to the first lower channel pattern, which are spaced apart from each other in the first direction.

18. The semiconductor device of claim 17, wherein the bit lines include an upper bit line in contact with the first upper channel pattern and a lower bit line in contact with the first lower channel pattern, and
wherein the upper bit line, the second upper channel pattern, the lower bit line and the second lower channel pattern are sequentially disposed in the first direction.

19. The semiconductor device of claim 17, wherein the bit lines include an upper bit line in contact with the first upper channel pattern and a lower bit line in contact with the first lower channel pattern, and
wherein the second upper channel pattern and the second lower channel pattern are disposed between the upper bit line and the lower bit line.

20. A semiconductor device, comprising:
a first channel pattern extending on a substrate in a first direction, the first channel pattern including a first surface and a second surface spaced apart from the first surface in the first direction;
a bit line in contact with the first surface of the first channel pattern and extending in a second direction, wherein the second direction intersects the first direction;
a second channel pattern in contact with the bit line and adjacent to the first channel pattern, and extending in the first direction;
an information storage element in contact with the second surface of the first channel pattern;
a word line disposed between the first channel pattern and the second channel pattern and adjacent to the information storage element in the first direction; and
a plate electrode spaced apart from the bit line in the first direction and in contact with the second channel pattern,
wherein at least a portion of the word line extends in a third direction, wherein the third direction intersects the first direction and the second direction,
wherein the second channel pattern includes a first impurity region in contact with the bit line, a second impurity region spaced apart from the first impurity region in the first direction, and a second channel region between the first impurity region and the second impurity region, and
wherein the second channel region overlaps the word line and the information storage element in the second direction.
